(19) United States
(12) Patent Application Publication
(10) Pub. No.: US 2023/0243041 A1
(43) Pub. Date: Aug. 3, 2023

(54) ETCHING COMPOSITIONS

(71) Applicant: TEXAS INSTRUMENTS INCORPORATED, Dallas, TX (US)

(72) Inventor: Simon Joshua JACOBS, Lucas, TX (US)

(21) Appl. No.: 17/587,614

(22) Filed: Jan. 28, 2022

(51) Int. Cl. C23F 1/34; H01L 21/02

(52) U.S. Cl. CPC C23F 1/34; H01L 21/02019

(57) ABSTRACT

An etching composition includes phosphate ions, pyrophosphate ions, polyphosphate ions, or a combination thereof and an oxidant. The etching composition has a neutral or basic pH.

### BACKGROUND

Copper can be etched by an oxidation-dissolution mechanism in which a top layer of copper metal is oxidized to copper oxide(s), and the copper oxide(s) are then dissolved by the action of agents in an aqueous solution. Common copper etchants utilized in wafer processing operate in an acidic pH range, often at a pH of about 5 and, in applications, at a pH of about 1 or less. Within the printed wiring board (PWB) industry, copper is often etched by an ammoniacal copper (II) solution at a pH of 9 or above.

### SUMMARY

In accordance with at least one example of this description, an etching composition comprises: an oxidant; and phosphate ions, pyrophosphate ions, polyphosphate ions, or a combination thereof, wherein the etching composition has a neutral or basic pH.

In accordance with at least one example of this description, an etching composition comprises: an oxidant; a phosphate salt; water; and an acid, wherein the etching composition comprises from 8 to 17, from 10 to 15, or from 12 to 14 mole percent of the oxidant, from 15 to 35, from 20 to 30, or from 23 to 28 mole percent of the phosphate salt, from 35 to 65, from 40 to 60, or from 45 to 55 mole percent water, and from 3 to 25, from 3 to 20, or from 5 to 15 mole percent of the acid and wherein the etching composition has a pH in a range of from 7 to 10.1.

In accordance with at least one example of this description, a method comprises: providing a mixture of an oxidant, a pyrophosphate salt, and water; and adjusting a pH of the mixture to a neutral or basic pH with an acid to form an etching composition.

In accordance with at least one example of this description, a method comprises: contacting a substrate with an etching composition, wherein: the substrate has a first exposed surface that includes copper and a second exposed surface that includes a metal selected from transition metals and post-transition metals, wherein the etching composition is configured to selectively etch the copper, includes: an oxidant; and phosphate ions, pyrophosphate ions, polyphosphate ions, or a combination thereof, and has a neutral or basic pH.

In accordance with at least one example of this description, production of a semiconductor wafer includes selectively etching copper from an exposed surface thereof via an etching composition and method of this description.

In accordance with at least one example of this description, a semiconductor wafer is produced via a method of this description.

### BRIEF DESCRIPTION OF THE DRAWINGS

FIG. 1 is a schematic representation of an etching composition in accordance with various examples.

FIG. 2 is a flow diagram of a method in accordance with various examples.

FIG. 3 is a flow diagram of a method in accordance with various examples.

FIG. 4A is a top view of an example substrate.

FIG. 4B is a cross-sectional view of an example substrate.

### DETAILED DESCRIPTION

A variety of electroplated metals and alloys that are useful in wafer processing tend to sustain damage or corrode responsive to exposure to conventional etchants. The selective etching of certain metals (e.g., copper) in the presence of these electroplated metals and alloys, can provide for the successful integration of the electroplated metals and alloys in semiconductor and PWB products.

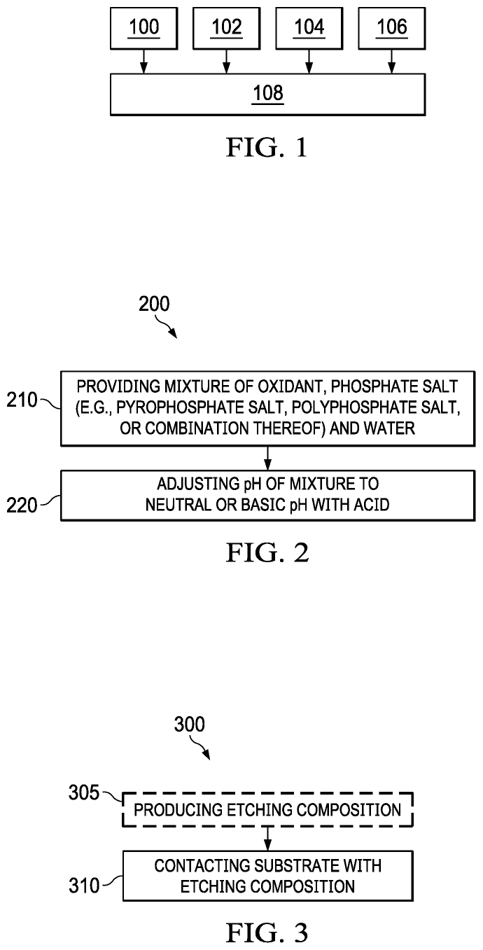

FIG. 1 is a schematic representation of an etching composition 108 in accordance with various examples. “Etching composition” and “etchant” are synonymous terms. Etching composition 108 includes an oxidant and one or more of phosphate ions, pyrophosphate ions, or polyphosphate ions. Etching composition 108 has a neutral or basic pH. The phosphate ions, pyrophosphate ions, polyphosphate ions, or the combination thereof can be provided by a polybasic pyrophosphate salt, either in pyrophosphate form or various states of hydrolysis or oligomerization, and protonated in equilibria determined by the pH of the etching composition, which is greater than or equal to 7.0. As described hereinbelow, etching composition 108 provides a near-neutral pH solution that can selectively etch copper (Cu), magnesium (Mg), vanadium (V), germanium (Ge), tungsten (W), molybdenum (Mo), rhenium (Re), lead (Pb), arsenic (As), antimony (Sb), or a combination thereof (referred to herein as “first” or “seed” metals). The elements: iron (Fe), nickel (Ni), cobalt (Co), tin (Sn), indium (In), gallium (Ga), zinc (Zn), tantalum (Ta), niobium (Nb), zirconium (Zr), aluminum (Al), hafnium (Hf), titanium (Ti), beryllium (Be) (referred to herein as “second metals”) can form an oxidized surface layer, but will resist etching due to the relative inertness of this surface layer. Said inert character is dependent on pH and temperature, with greatest selectivity exhibited near room temperature and near neutral pH, e.g., between 7 and 8. Additional elements which may be passivated or etched and are more labile under the conditions described herein include manganese (Mn), chromium (Cr), cadmium (Cd), bismuth (Bi), and silver (Ag). Varying the conditions can lead to such metals being etched or not. A method of selective sequential etching involves subjecting a first metal film to the etching composition at a first temperature and pH to etch said first metal film, followed by etching a second metal film, originally underlying the first metal film, by exposing the second metal film to a similar etching composition at higher temperature and/or higher pH. Varying degrees of selectivity are possible through such film-specific modifications of the etching composition 108 without deviating from the basic principles of this description. The etching composition 108 can be utilized to etch “first” or “seed” metals in the presence of metals (“second” metals”) of another layer of a substrate. In this description, “selectively etching” a first metal relative to a second metal indicates that an etch rate of the first metal is greater than an etch rate of the second metal.

As shown in FIG. 1, combining an oxidant 100, a source 102 of phosphate ions, pyrophosphate ions, polyphosphate ions, or the combination thereof, an acid 104, and water 106 may form an etching composition 108. As shown in FIG. 2, which is a schematic flow diagram of a method 200 of manufacturing etching composition 108 in accordance with various examples, etching composition 108 can be formed by providing a mixture of oxidant 100, a phosphate salt (e.g., a pyrophosphate salt, a polyphosphate salt) as the source 102 of phosphate ions, pyrophosphate ions, polyphosphate ions, or the combination thereof, and water 106, as shown at 210, and adjusting the pH of the mixture to neutral or basic pH (e.g., a pH of equal to or greater than 7) with acid 104 to provide etching composition 108.

Oxidant 100 includes an oxidant capable of oxidizing a first metal, also referred to herein as a “seed” metal, (e.g., copper, etc.) to an oxide (e.g., copper oxide, etc.) at the etchant pH. Examples of such an oxidant 100 include a peroxide, a perborate, a percarbonate, an organic peracid, a hypochlorite, or a combination thereof. For example, oxidant 100 can include sodium perborate monohydrate.

The source 102 of phosphate ions, pyrophosphate ions, polyphosphate ions, or the combination thereof can include a phosphate salt or an aqueous solution of a phosphate salt. Although shown as being introduced separately to provide etching composition 108, water 106 can be included in oxidant 100, source 102, mineral acid, 30, or a combination thereof. The phosphate salt of source 102 can include a pyrophosphate salt, a polyphosphate salt, or a combination thereof. For example, pyrophosphate ions in etching composition 108 can be provided by dissolution of a pyrophosphate salt. The pyrophosphate salt can include a tetrabasic salt of pyrophosphoric acid. Examples of such a tetrabasic salt of pyrophosphate acid include tetrasodium pyrophosphate and tetrapotassium pyrophosphate. Alternatively or also, pyrophosphate ions in etching composition 108 can be provided by dissolution of a polyphosphate salt as source 102. Examples of such a polyphosphate salt include sodium or potassium tripolyphosphate, or another alkali polyphosphate salt which provides a non-zero equilibrium concentration of pyrophosphate ions. Source 102 can provide the phosphate ions, pyrophosphate ions, polyphosphate ions, or the combination thereof (e.g., can be a solution of the phosphate salt dissolved in water 106). The phosphate ions, pyrophosphate ions, polyphosphate ions, or the combination thereof can be formed responsive to source 102 (e.g., phosphate salt) being dissolved in water 106 of etching composition 108, and water 106 can be introduced into etching composition 108 via oxidant 100 (e.g., in examples where oxidant 100 includes water 106), source 102 (e.g., in examples where source 102 includes water 106), mineral acid 104 (e.g., in examples where mineral acid 104 includes water 106), or separately via water 106.

Acid 104 can include a mineral acid. For example, acid 104 can include phosphoric acid, hydrohalic acid (e.g., hydrochloric acid, hydrofluoric acid, etc.), sulfuric acid, or a combination thereof. Acid 104 can include an aqueous mineral acid of the mineral acid and water 106.

The phosphate ions, pyrophosphate ions, polyphosphate ions, or the combination thereof of etching composition 108 can be provided by combining oxidant 100, a pyrophosphate salt as the source 102 of phosphate ions, pyrophosphate ions, polyphosphate ions, or the combination thereof, water 106, and an amount of acid 104 to provide the neutral or basic pH. The phosphate ions, pyrophosphate ions, polyphosphate ions, or the combination thereof (e.g., pyrophosphate ions) buffer the etching composition 108.

In examples, etching composition 108 includes from 5% to 20%, from 10% to 15%, or from 11% to 13% by mass of the oxidant 100 (e.g., sodium perborate monohydrate), from 5% to 30%, from 15% to 28%, or from 23 to 26% by mass of the phosphate salt 102 (e.g., tetrapotassium pyrophosphate), from 40 to 80%, from 50 to 70%, or from 55 to 60% by mass of water 106, and from 3% to 8% by mass of the acid 104 (e.g., phosphoric acid). In examples, etching composition 108 includes from 8 to 17, from 10 to 15, or from 12 to 14 mole percent of the oxidant 100 (e.g., sodium perborate monohydrate), from 15 to 35, from 20 to 30, or from 23 to 28 mole percent of the phosphate salt 102 (e.g., tetrapotassium pyrophosphate), from 35 to 65, from 40 to 60, or from 45 to 55 mole percent water 106, and from 3 to 25, from 3 to 20, or from 5 to 15 mole percent acid 104 (e.g., phosphoric acid).

As noted above, in examples, source 102 of phosphate ions, pyrophosphate ions, polyphosphate ions, or the combination thereof includes a pyrophosphate salt. In such examples, etching composition 108 can include oxidant 100, the pyrophosphate salt as a source 102 of phosphate ions, pyrophosphate ions, polyphosphate ions, or the combination thereof, water 106, and acid 104, and has a pH in a range from 7 to 10.1. In examples, etching composition 108 can include from 5% to 20%, from 10% to 15%, or from 11% to 13% by mass of oxidant 100 (e.g., sodium perborate monohydrate), from 5% to 30%, from 15% to 28%, or from 23 to 26% by mass of source 102 including tetrapotassium pyrophosphate, from 40 to 80%, from 50 to 70%, or from 55 to 60% by mass of water 106, and from 3% to 8% by mass of acid 104 (e.g., phosphoric acid). Alternatively or also, the oxidant 100 includes a peroxide, a percarbonate, an organic peracid, a hypochlorite, another perborate, or a combination thereof in lieu of or with the sodium perborate monohydrate. Alternatively or also, the oxidant 100 can include a perborate (e.g., sodium perborate monohydrate), a percarbonate (e.g., sodium percarbonate), hydrogen peroxide, or a combination thereof. Alternatively or also, the acid 104 can include an aqueous mineral acid (e.g., phosphoric acid, hydrohalic acid (e.g., hydrochloric acid, hydrofluoric acid, etc.), sulfuric acid, or a combination thereof).

As noted hereinabove, etching composition 108 has a pH of greater than or equal to 7. In examples, etching composition has a pH of greater than 7. Etching composition 108 can have a pH of less than or equal to 10, 9, or 8. In examples, etching composition 108 has a pH in a range of greater than 7 (e.g., 7.05, 7.1, 7.2) to 10.1, greater than 7 (e.g., 7.05, 7.1, 7.2) to 9, or greater than 7 (e.g., 7.05, 7.1, 7.2) to 8. In examples, etching composition 108 has a slightly basic pH (also referred to herein as a “near-neutral pH”), which herein indicates a pH in a range of greater than 7 to 7.5 (e.g., 7.05, 7.1, 7.2, 7.3, 7.4, or 7.5). With reference to FIG. 2, an adjustment of the pH of etching composition 108 to neutral or basic pH (e.g., within the range of 7.0 to 10.1) can be effected by combining acid 104 (e.g., an aqueous solution of mineral acid in water 106), a basic solution containing the phosphate ions, pyrophosphate ions, polyphosphate ions, or the combination thereof as source 102 of phosphate ions, pyrophosphate ions, polyphosphate ions, or the combination thereof, and a solution of oxidant 100. For example, the basic solution containing the phosphate ions, pyrophosphate ions, polyphosphate ions, or the combination thereof can be created by dissolving a phosphate salt source 102 in water 106.

As described, copper (e.g., copper seed metal for electroplating semiconductor wafers) can be etched by oxidizers in acidic or basic solution. However, certain metals referred to herein as “second” metals (e.g., transition metals or post-transition metals, such as iron (Fe), nickel (Ni), cobalt (Co), tin (Sn), indium (In), gallium (Ga), zinc (Zn), tantalum (Ta), niobium (Nb), zirconium (Zr), aluminum (Al), hafnium (Hf), titanium (Ti), beryllium (Be)) can be corroded under both acidic and basic conditions. Some approaches employ basic pH or near-neutral conditions. However, such conventional processes, such as the ammonia process described above, are challenging due to hazards (e.g., ammonia fumes) and the demanding conditions (e.g., high temperatures) present during such processes.

Etching composition 108 provides a near-neutral pH solution that can selectively etch copper (Cu), magnesium (Mg), vanadium (V), germanium (Ge), tungsten (W), molybdenum (Mo), rhenium (Re), lead (Pb), arsenic (As), antimony (Sb), a combination thereof, or other metals (e.g., “first” or “seed” metals) in the presence of metals (e.g., “second metals”) of another layer of a substrate. In examples, etching composition 108 is configured to etch copper or another first or seed metal at a rate of at least 10, 20, 30, 40, or 50 nanometers (nm) per minute. In examples, the etching composition 108 can selectively etch the copper or other first or seed metal at room temperature (e.g., a temperature in the range of 68 to 72° F. (20 to 22° C.)), at a temperature above room temperature, or both at room temperature and at a temperature above room temperature. In examples, etching composition 108 is configured to etch copper, another first or seed metal, or a combination thereof at a rate of at least 50 nm/min at a temperature in the range of 68 to 72° F. (20 to 22° C.).

Etching composition 108 is configured to passivate a second metal selected from transition metals and post-transition metals, such that the etching composition 108 selectively etches copper, or another first or seed metal relative to the second metal or alloys or combinations of two or more thereof. The second metal can include iron (Fe), nickel (Ni), cobalt (Co), tin (Sn), indium (In), gallium (Ga), zinc (Zn), tantalum (Ta), niobium (Nb), zirconium (Zr), aluminum (Al), hafnium (Hf), titanium (Ti), beryllium (Be), or alloys or combinations thereof. In examples, the second metal can include nickel (Ni), iron (Fe), indium (In), or alloys or combinations thereof. In examples, interaction of the second metal(s) with the etching composition 108 provides a passivation layer of less than or equal to about 100A on the second metal that reduces or eliminates etching of the second metal by the etching composition 108.

Referring again to FIG. 2, the method 200 includes, at 210, providing a mixture of oxidant 100, a pyrophosphate salt as source 102, and water 106. The method 200 includes, at 220, adjusting a pH of the mixture to a neutral or basic pH with an acid (e.g., a mineral acid) to form etching composition 108. As described above, in examples, (i) the oxidant 100 can include a peroxide, a perborate, a percarbonate, an organic peracid, a hypochlorite, or a combination thereof, (ii) the pyrophosphate salt as source 102 can include tetrapotassium pyrophosphate, (iii) the acid 104 can include phosphoric acid; or (iv) a combination of (i) to (iii). In examples, the oxidant 100 includes a peroxide, a perborate, a percarbonate, an organic peracid, a hypochlorite, or a combination thereof, the pyrophosphate salt as source 102 includes tetrapotassium pyrophosphate, and the acid 104 includes phosphoric acid.

FIG. 3 is a schematic flow diagram of a method 300 for etching via the etching composition 108 in accordance with various examples. Method 300 includes, at 310, contacting a substrate with an etching composition 108 as described herein, where the substrate includes a first exposed surface that includes a first metal (e.g., copper, or another first metal) and a second exposed surface that includes a second metal selected from transition metals and post-transition metals. The etching composition 108 is configured to selectively etch the first metal relative to the second metal, and includes oxidant 100, and phosphate ions, pyrophosphate ions, polyphosphate ions, or the combination thereof. The etching composition 108 has a neutral or basic pH.

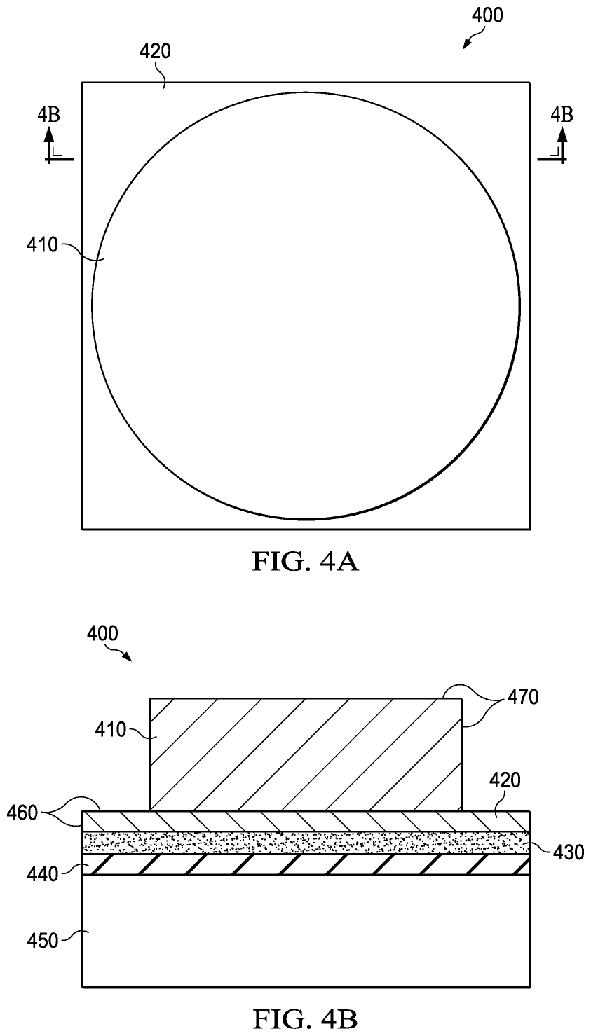

The substrate can include any substrate having the first exposed surface and the second exposed surface. In examples, the substrate includes a semiconductor wafer. In examples, the substrate includes a magnetic concentrator plate. Such a magnetic concentrator plate is now described with reference to FIG. 4A, which is a schematic top view of a magnetic concentrator plate substrate 400, and FIG. 4B, which is a schematic cross section view of magnetic concentrator plate substrate 400 of FIG. 4A. Concentrator plate 400 includes a second metal layer 410 containing the second metal, a first metal or “seed layer” 420 containing the first metal or seed metal, adhesion layer 430, dielectric layer 440, and support layer 450. First exposed surface 460 includes the exposed surface of first or seed layer 420, which includes copper, or another first or seed metal, and second exposed surface 470 includes the exposed surface of second metal layer 410, which includes a metal (e.g., second metal) selected from transition metals and post-transition metals. For example, first metal or seed layer 420 can include a copper first or seed layer, and second metal layer 410 can include a variety of alloys containing nickel, iron, and/or cobalt that may have a permanent magnetization. For example, Ni₈₀Fe₂₀ having 80 mole percent nickel and 20 mole percent iron.

The first metal or seed layer 420 can have any thickness. For example, the first metal or seed layer 420 can have a thickness of 0.1 to 5 micrometers (μm), or 0.1, 0.2, 0.3, 0.4, 0.5, 1, 2, 3, 4, or 5 μm. The second metal layer 410 can have any thickness. For example, the second metal layer 410 can have a thickness of 5, 10, 15, or 20 μm. Adhesion layer 430 can be configured for sputtering of first metal or seed layer 420 on support layer 450. Adhesion layer 430 can include any adhesion material. Examples of an adhesion material include titanium, tungsten, tantalum, or a combination thereof, such as a titanium alloy (e.g., titanium tungsten (TiW)). Adhesion layer 430 can have any suitable thickness. For example, adhesion layer 430 can have a thickness of 0.1 to 5 micrometers (μm), or 0.1, 0.2, 0.3, 0.4, 0.5, 1, 2, 3, 4, or 5 μm. Support layer 450 can include a semiconductor wafer (e.g., silicon (Si) wafer). Dielectric layer 440 can be formed on support layer 450, and can have any thickness. For example, dielectric layer 440 can include one or more dielectric layers and can have a thickness from micrometers to millimeters, e.g., of 0.1 to 5 micrometers (μm), or 0.1, 0.2, 0.3, 0.4, 0.5, 1, 2, 3, 4, or 5 μm.

A substrate etched via etching composition 108 can include a different number or order of layers than substrate 400 described with reference to example FIG. 4A and FIG. 4B. For example, substrate 400 may include two or more or no dielectric layer 440, in embodiments. Also, it is noted that although the first metal can include a seed metal of a seed layer, the first metal may not be a seed metal (e.g., of a seed layer). For example, first metal layer 420 may not be a seed layer.

Method 300 enables the first metal (e.g., copper or other first metal or seed metal of first metal or seed layer 420) to be etched at a faster rate than the second metal (e.g., transition metal and/or post-transition metal of second metal layer 410). For example, the etching composition 108 can be utilized to etch copper, or other first or seed metal of first metal or seed layer 420 at an etch rate that is (depending on the temperature and pH) greater than or equal to 1.5, 2, 3, 4, 5, 6, 7, 8, 9, 10, 50, 100, 500, or 1000 times an etch rate of the transition metal and/or post-transition metal of second metal layer 410.

Method 300 can further include, at 305, producing the etching composition 108, as described above with regard to FIG. 1 and FIG. 2 (e.g., by providing a mixture of the oxidant 100, a pyrophosphate salt as source 102 of phosphate ions, pyrophosphate ions, polyphosphate ions, or the combination thereof, and water 106, and adjusting the pH of the mixture to the neutral or basic pH with acid 104).

Also described herein is a semiconductor wafer or other substrate, the production of which includes selectively etching a first metal (e.g., copper, or another first or seed metal) from a first exposed surface 460 thereof relative to etching of a second metal (e.g., a transition and/or post-transition metal) from a second exposed surface 470 thereof via method 300. Although described herein with reference to a particular magnetic concentrator plate as the substrate 400, a variety of substrates can be etched via the described etching composition 108 and method 300, provided the substrate includes a first exposed surface 460 and second exposed surface 470, the first exposed surface including a first metal that is selectively etched by the etching composition 108 relative to a second metal of the second exposed surface 470.

The etching composition 108 of this description can provide for selective etching of first or seed metals (e.g., copper, or another first or seed metal) relative to etching of a second metal (e.g., iron, nickel, indium, or a combination thereof). Pyrophosphate ions in the etching composition 108 complex (e.g., form a union held together by chemical forces with) the etched copper (e.g., the Cu²⁺ formed responsive to the oxidation of the copper metal by oxidant 100) to form uncommon transition metal complexes, thus keeping the Cu²⁺ from decomposing the oxidant 100. Thus, etching composition 108 can exhibit a prolonged useful or “bath” life (e.g., 1, 2, 3 weeks or more). By passivating oxides of the second metals of the second exposed surface 470 of the substrate 400, etching composition 108 can selectively etch a first metal (e.g., copper, or other first or seed metals) of first exposed surface 460 of substrate 400 relative to the etching of second metal of the second exposed surface 470 of the substrate 400. In examples, the etch rate of the metal (e.g., copper, etc.) of the first exposed surface of the substrate 400 provided by the etching composition 108 increases as the pH approaches neutral (pH 7), and the etching composition 108 is configured to have a near-neutral pH.

By utilizing an etching composition as described herein, including an aqueous solution having a mixture of phosphate, pyrophosphate, and polyphosphate ions stabilized close to a neutral pH of 7 (e.g., a “near-neutral pH”), attack on certain metals (e.g., second metal(s)) by the etching solution 108 can be reduced or eliminated. The second metals include many metals which show corrosion at acidic pH and oxidizing conditions, but are passivated or inert at basic pH with similar oxidants. Examples of such second metals include nickel (Ni), iron (Fe), indium (In) and alloys thereof. The pyrophosphate component of the etching composition 108 can serve both to buffer the pH of the etching composition 108 and to complex the metal ions (e.g., Cu²⁺, Ti³⁺) as the metals are dissolved, thus preventing the metal ions from precipitating from the etchant composition 108.

The etching composition 108 of this description provides useful first or seed metal (e.g., copper) etch rates and uniformity, and can eliminate attack on sensitive (e.g., second) metals.

### ADDITIONAL EXAMPLES

The following are non-limiting, specific examples of an etching composition:

In a first example, an etching composition includes: an oxidant; and phosphate ions, pyrophosphate ions, polyphosphate ions, or a combination thereof, wherein the etching composition has a neutral or basic pH.

A second example can include the etching composition of the first example, wherein the etching composition has a pH of less than or equal to 10, 9, or 8.

A third example can include the example of any one of the first or second examples, wherein the etching composition has a pH in a range of 7.0 to 10.1.

A fourth example can include the etching composition of the third example, wherein the etching composition has a pH in a range of 7.1 to 9.0.

A fifth example can include the etching composition of any one of the first to fourth examples, wherein the oxidant includes a peroxide, a perborate, a percarbonate, an organic peracid, a hypochlorite, or a combination thereof.

A sixth example can include the etching composition of any one of the first to fifth examples, wherein the etching composition is configured to etch copper at a rate of at least 10, 20, 30, 40, or 50 nanometers (nm) per minute at a temperature in the range of 68 to 72° F. (20 to 22° C.).

A seventh example can include the etching composition of the sixth example, wherein the etching composition is configured to etch copper at the rate of at least 50 nm/min at a temperature in the range of 68 to 72° F. (20 to 22° C.).

An eighth example can include the etching composition of any one of the first to seventh examples, wherein the etching composition is configured to passivate a metal selected from transition metals and post-transition metals, such that the etching composition selectively etches copper relative to the metal or an alloys or combination of two or more thereof.

A ninth example can include the etching composition of the eighth example, wherein the metal selected from transition metals and post-transition metals includes that includes a metal selected from iron (Fe), nickel (Ni), cobalt (Co), tin (Sn), indium (In), gallium (Ga), zinc (Zn), tantalum (Ta), niobium (Nb), zirconium (Zr), aluminum (Al), hafnium (Hf), titanium (Ti), beryllium (Be), alloys or combinations thereof.

A tenth example can include the etching composition of any one of the first to ninth examples, wherein a mixture of the oxidant, a pyrophosphate salt, water, and an amount of acid to provide the neutral or basic pH is configured to provide the phosphate ions, pyrophosphate ions, polyphosphate ions, or the combination thereof.

In an eleventh example, an etching composition includes: an oxidant; a phosphate salt; water; and an acid, wherein the etching composition includes from 8 to 17, from 10 to 15, or from 12 to 14 mole percent of the oxidant, from 15 to 35, from 20 to 30, or from 23 to 28 mole percent of the phosphate salt, from 35 to 65, from 40 to 60, or from 45 to 55 mole percent water, and from 3 to 25, from 3 to 20, or from 5 to 15 mole percent of the acid and wherein the etching composition has a pH in a range of from 7 to 10.1.

A twelfth example can include the etching composition of the eleventh example, wherein the phosphate salt includes a tetrabasic salt of pyrophosphoric acid, an alkali polyphosphate salt, or a combination thereof.

A thirteenth example can include the etching composition of any one of the eleventh or twelfth examples, wherein the oxidant includes a peroxide, a perborate, a percarbonate, an organic peracid, a hypochlorite, or a combination thereof.

A fourteenth example can include the etching composition of the thirteenth example, wherein the oxidant includes sodium perborate, sodium percarbonate, hydrogen peroxide, or a combination thereof.

A fifteenth example can include the etching composition of any one of the eleventh to fourteenth examples, wherein the acid includes an aqueous mineral acid.

In a sixteenth example, a method includes: providing a mixture of an oxidant, a pyrophosphate salt, and water; and adjusting a pH of the mixture to a neutral or basic pH with an acid to form an etching composition.

A seventeenth example can include the method of the sixteenth example: (i) wherein the oxidant includes a peroxide, a perborate, a percarbonate, an organic peracid, a hypochlorite, or a combination thereof; (ii) wherein the pyrophosphate salt includes tetra potassium pyrophosphate; (iii) wherein the acid includes phosphoric acid; or (iv) a combination thereof.

In an eighteenth example, a method includes: contacting a substrate with an etching composition, wherein: the substrate has a first exposed surface that includes copper and a second exposed surface that includes a metal selected from iron (Fe), nickel (Ni), cobalt (Co), tin (Sn), indium (In), gallium (Ga), zinc (Zn), tantalum (Ta), niobium (Nb), zirconium (Zr), aluminum (Al), hafnium (Hf), titanium (Ti), beryllium (Be), alloys or combinations thereof, the etching composition is according to any one of the first to tenth examples and is configured to selectively etch the copper, the etching composition includes: the oxidant; and phosphate ions, pyrophosphate ions, polyphosphate ions, or the combination thereof, and the etching composition has the neutral or basic pH.

A nineteenth example can include the method of the eighteenth example, wherein the substrate includes a semiconductor wafer.

A twentieth example can include the method of the nineteenth example further including producing the etching composition by providing a mixture of the oxidant, a pyrophosphate salt, and water, and adjusting the pH of the mixture to the neutral or basic pH with an acid.

In a twenty first example, production of a semiconductor wafer includes selectively etching copper from an exposed surface thereof via the method of any one of the eighteenth to twentieth examples.

A twenty second example includes the semiconductor wafer produced via the twenty first example.

Unless otherwise stated, “about,” “approximately,” or “substantially” preceding a value means +/−10 percent of the stated value. Modifications are possible in the described examples, and other examples are possible within the scope of the claims.

What is claimed is:

1. An etching composition comprising:
an oxidant; and
phosphate ions, pyrophosphate ions, polyphosphate ions, or a combination thereof,
wherein the etching composition has a neutral or basic pH.

2. The etching composition of claim 1, wherein the etching composition has a pH of less than or equal to 10.

3. The etching composition of claim 1, wherein the etching composition has a pH in a range of 7.0 to 10.1.

4. The etching composition of claim 3, wherein the etching composition has a pH in a range of 7.1 to 9.0.

5. The etching composition of claim 1, wherein the oxidant includes a peroxide, a perborate, a percarbonate, an organic peracid, a hypochlorite, or a combination thereof.

6. The etching composition of claim 1, wherein the etching composition is configured to etch copper at a rate of at least 10 nanometers (nm) per minute at a temperature in a range of 68 to 72° F. (20 to 22° C.).

7. The etching composition of claim 6, wherein the etching composition is configured to etch copper at a rate of at least 50 nm/min at a temperature in the range of 68 to 72° F. (20 to 22° C.).

8. The etching composition of claim 1, wherein the etching composition is configured to passivate a metal selected from transition metals and post-transition metals, such that the etching composition selectively etches copper relative to the metal or an alloy or combination of two or more thereof.

9. The etching composition of claim 8, wherein the metal selected from transition metals and post-transition metals includes iron (Fe), nickel (Ni), cobalt (Co), tin (Sn), indium (In), gallium (Ga), zinc (Zn), tantalum (Ta), niobium (Nb), zirconium (Zr), aluminum (Al), hafnium (Hf), titanium (Ti), beryllium (Be), or alloys or combinations thereof.

10. The etching composition of claim 1, wherein a mixture of the oxidant, a pyrophosphate salt, water, and an amount of acid to provide the neutral or basic pH is configured to provide the phosphate ions, pyrophosphate ions, polyphosphate ions, or the combination thereof.

11. An etching composition comprising:
an oxidant;
a phosphate salt;
water; and
an acid,
wherein the etching composition comprises from 10 to 15 mole percent of the oxidant, from 20 to 30 mole percent of the phosphate salt, from 40 to 60 mole percent of the water, and from 3 to 20 mole percent of the acid, and
wherein the etching composition has a pH in a range of from 7 to 10.1.

12. The etching composition of claim 11, wherein the phosphate salt comprises a tetrabasic salt of pyrophosphoric acid, an alkali polyphosphate salt, or a combination thereof.

13. The etching composition of claim 11, wherein the oxidant comprises a peroxide, a perborate, a percarbonate, an organic peracid, a hypochlorite, or a combination thereof.

14. The etching composition of claim 13, wherein the oxidant comprises sodium perborate, sodium percarbonate, hydrogen peroxide, or a combination thereof.

15. The etching composition of claim 11, wherein the acid comprises an aqueous mineral acid.

16. A method comprising:
providing a mixture of an oxidant, a pyrophosphate salt, and water; and
adjusting a pH of the mixture to a neutral or basic pH with an acid to form an etching composition.

17. The method of claim 16:
(i) wherein the oxidant comprises a peroxide, a perborate, a percarbonate, an organic peracid, a hypochlorite, or a combination thereof;
(ii) wherein the pyrophosphate salt comprises tetra potassium pyrophosphate;
(iii) wherein the acid comprises phosphoric acid; or
(iv) a combination thereof.

18. A method comprising:
contacting a substrate with an etching composition, the etching composition including an oxidant and one or more of phosphate ions, pyrophosphate ions, or polyphosphate ions, the etching composition having a neutral or basic pH, wherein:
the substrate has a first exposed surface that includes copper and a second exposed surface that includes a metal selected from iron (Fe), nickel (Ni), cobalt (Co), tin (Sn), indium (In), gallium (Ga), zinc (Zn), tantalum (Ta), niobium (Nb), zirconium (Zr), aluminum (Al), hafnium (Hf), titanium (Ti), beryllium (Be), alloys or combinations thereof;
the etching composition is configured to selectively etch the copper relative to the metal selected from selected from iron (Fe), nickel (Ni), cobalt (Co), tin (Sn), indium (In), gallium (Ga), zinc (Zn), tantalum (Ta), niobium (Nb), zirconium (Zr), aluminum (Al), hafnium (Hf), titanium (Ti), beryllium (Be), alloys or combinations thereof.

19. The method of claim 18, wherein the substrate includes a semiconductor wafer.

20. The method of claim 18 further including producing the etching composition by providing a mixture of the oxidant, a pyrophosphate salt, and water, and adjusting the pH of the mixture to the neutral or basic pH with an acid.
